(19) United States
(12) Patent Application Publication
(10) Pub. No.: US 2013/0098444 A1
(43) Pub. Date: Apr. 25, 2013

(54) POLYCRYSTALLINE SILICON THIN-FILM FORMING METHOD, POLYCRYSTALLINE SILICON THIN-FILM SUBSTRATE, SILICON THIN-FILM SOLAR CELL, AND SILICON THIN-FILM TRANSISTOR DEVICE

(71) Applicant: PANASONIC CORPORATION, Osaka (JP)

(72) Inventor: Takahiro KAWASHIMA, Osaka (JP)

(73) Assignee: PANASONIC CORPORATION, Osaka (JP)

(21) Appl. No.: 13/716,529

(22) Filed: Dec. 17, 2012

Related U.S. Application Data
(63) Continuation of application No. PCT/JP2011/003399, filed on Jun. 15, 2011.

(30) Foreign Application Priority Data
Jun. 25, 2010 (JP) 2010-145461

(51) Int. Cl. H01L 21/02; H01L 29/786; H01L 31/0368; H01L 29/04

(52) U.S. Cl. CPC H01L 21/02532; H01L 29/04; H01L 29/78675; H01L 29/78678; H01L 31/03682
USPC 136/258; 438/488; 257/49; 257/66

(57) ABSTRACT

A polycrystalline silicon thin-film forming method includes: preparing a substrate; forming a precursor of a first silicon thin film including a first polycrystalline silicon phase and a non-crystalline silicon phase; exposing the first polycrystalline silicon phase; and growing, above the first silicon thin film which the first polycrystalline silicon phase is exposed, a second polycrystalline silicon phase using the first polycrystalline silicon phase as a seed crystal by a plasma chemical vapor deposition method, wherein the first polycrystalline silicon phase is formed continuously in any direction perpendicular to a thickness direction of the first silicon thin film.

### CROSS REFERENCE TO RELATED APPLICATIONS

This is a continuation application of PCT International Application No. PCT/JP2011/003399 filed on Jun. 15, 2011, designating the United States of America, which is based on and claims priority of Japanese Patent Application No. 2010-145461 filed on Jun. 25, 2010. The entire disclosures of the above-identified applications, including the specifications, drawings and claims are incorporated herein by reference in their entirety.

### FIELD

One or more exemplary embodiments disclosed herein relate generally to polycrystalline silicon thin-film forming methods, polycrystalline silicon thin-film substrates, silicon thin-film solar cells, and silicon thin-film transistor devices.

### BACKGROUND

For manufacturing thin film silicon solar cells, thin film transistors, organic EL display devices, and liquid crystal display devices, it is required to form a polycrystalline silicon thin film, which is a functional layer, at a high speed. Furthermore, especially for manufacturing a thin-film silicon solar cell including a polycrystalline silicon thin film, it is required to make the polycrystalline silicon thin film as thick as 2 to 3 μm to enhance absorption ratio for solar light and increase conversion efficiency.

As a method of forming such a polycrystalline silicon thin-film forming method, conventionally, a method is available in which a microcrystalline silicon thin film is formed by a method of diluting source gas with a large flow of hydrogen gas (equal to or less than 5% of source gas) (see Patent Literature 1 (PTL) and PTL 2, for example). In this method, a microcrystalline silicon thin film is grown by: forming amorphous (non-crystalline) silicon on a substrate; etching a large part of the amorphous silicon with hydrogen radical in plasma; and crystallizing the silicon thin film.

### CITATION LIST

### Patent Literature

[PTL 1] Japanese Unexamined Patent Application Publication No. H08-148690

[PTL 2] Japanese Unexamined Patent Application Publication No. H08-097427

### SUMMARY

### Technical Problem

In the conventional polycrystalline silicon thin-film forming method, a silicon thin film having a desired thickness is formed by repeating: forming a film of amorphous silicon on an insulator film by resolving source gas including a silicon element introduced to a reaction chamber of a plasma chemical vapor deposition (CVD) device; and etching and crystallizing a large part of the amorphous silicon. When growing the polycrystalline silicon thin film by the above plasma CVD method, it is in principle difficult to form the polycrystalline silicon thin film at a high speed, since the growth rate of the polycrystalline silicon thin film is, for example, a few nm/min.

The following describes the present disclosure specifically. FIG. 25 is a flowchart showing the conventional polycrystalline silicon thin-film forming method. In the conventional polycrystalline silicon thin-film forming method, a hydrogen plasma process is included in a polycrystalline silicon thin film forming process, in order to crystallize a silicon film. As shown in FIG. 25, the polycrystalline silicon thin film having a desired thickness is formed by: forming an amorphous silicon film above a substrate (S21); etching and crystallizing a large part of the amorphous silicon film by irradiating the amorphous silicon film with hydrogen plasma (S22); and then repeating (i) forming and (ii) etching and crystallizing (S23). In this case, for example, a polycrystalline silicon thin film having a thickness of approximately 0.1 to 5 nm is formed by (i) forming and (ii) etching and crystallizing for one cycle. Therefore, it takes approximately two hours to form a polycrystalline silicon thin film having a thickness of 50 nm, since it is required to repeat (i) forming and (ii) etching and crystallizing for 10 to 500 cycles.

Therefore, to form a polycrystalline silicon thin film for use in a solar cell, in which a polycrystalline silicon thin film of a thick film having a thickness of as much as approximately 2 to 3 μm is required, by the above-described polycrystalline silicon thin-film forming method, it is required to repeat the above processes for a plurality of times. Generally, a film having a thickness of pm-order is called a thick film. Thus, it takes a long time to manufacture a polycrystalline silicon thin film, which means it is difficult to form such a polycrystalline silicon thin film with low cost and high throughput.

Furthermore, in the process of the plasma CVD method in the conventional technique, usage efficiency of the source gas is less than 5% which is low rate. Therefore, it takes a long time to grow a polycrystalline silicon thin film of a thick film, which causes a problem that cost for material is increased.

One non-limiting and exemplary embodiment provides a polycrystalline silicon thin-film forming method, a polycrystalline silicon thin-film substrate, a silicon thin-film solar cell, and a silicon thin-film transistor device by which a polycrystalline silicon thin film can be formed at a high speed.

### Solution to Problem

In one general aspect, the techniques disclosed here feature a polycrystalline silicon thin-film forming method, the method including:

preparing a substrate; forming, above the substrate, a precursor of a first silicon thin film including a first polycrystalline silicon phase and a non-crystalline silicon phase; exposing the first polycrystalline silicon phase by etching the precursor of the first silicon thin film by a predetermined chemical etching process in which the non-crystalline silicon phase is etched preferentially over the first polycrystalline silicon phase; and growing, above the first silicon thin film which the first polycrystalline silicon phase is exposed, a second polycrystalline silicon phase using the first polycrystalline silicon phase as a seed crystal by a plasma chemical vapor deposition method, wherein the first polycrystalline silicon phase is formed continuously in a direction perpendicular to a thickness direction of the first silicon thin film.

These general and specific aspects may be implemented using a system, a method, an integrated circuit, a computer program, or a computer-readable recording medium such as a CD-ROM, or any combination of systems, methods, integrated circuits, computer programs, or computer-readable recording media.

Additional benefits and advantages of the disclosed embodiments will be apparent from the Specification and Drawings. The benefits and/or advantages may be individually obtained by the various embodiments and features of the Specification and Drawings, which need not all be provided in order to obtain one or more of such benefits and/or advantages.

### Advantageous Effects

The polycrystalline silicon thin-film forming method according to one or more exemplary embodiments or features disclosed herein provides a polycrystalline silicon thin-film forming method, a polycrystalline silicon thin-film substrate, a silicon thin-film solar cell, and a silicon thin-film transistor device by which a polycrystalline silicon thin film can be formed at a high speed.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a schematic view of a plasma CVD device used in forming of a polycrystalline silicon thin-film substrate according to Embodiment 1.

FIG. 2 is a flowchart showing a forming process of the polycrystalline silicon thin film according to Embodiment 1.

FIG. 3A shows a polycrystalline silicon thin-film forming method according to Embodiment 1.

FIG. 3B shows the polycrystalline silicon thin-film forming method according to Embodiment 1.

FIG. 3C shows the polycrystalline silicon thin-film forming method according to Embodiment 1.

FIG. 4A is a schematic diagram for illustrating a principle of removing an amorphous component using hydrogen plasma according to Embodiment 1.

FIG. 4B is a schematic diagram for illustrating a principle of removing the amorphous component using hydrogen plasma according to Embodiment 1.

FIG. 4C is a schematic diagram for illustrating a principle of removing the amorphous component using hydrogen plasma according to Embodiment 1.

FIG. 4D is a schematic diagram for illustrating a principle of removing the amorphous component using hydrogen plasma according to Embodiment 1.

FIG. 5 shows a hydrogen plasma condition for dry etching according to Embodiment 1.

FIG. 6 shows a mc-Si film-forming condition according to Embodiment 1.

FIG. 7 shows substrate temperature dependency according to Embodiment 1.

FIG. 8 shows pressure dependency according to Embodiment 1.

FIG. 9 shows interelectrode distance dependency according to Embodiment 1.

FIG. 10A is a cross-section TEM picture of a silicon thin-film substrate according to Embodiment 1.

FIG. 10B is a cross-section TEM picture of the silicon thin-film substrate according to Embodiment 1.

FIG. 11A is a cross-sectional view showing a polycrystalline silicon thin-film forming method according to Embodiment 2.

FIG. 11B is a cross-sectional view showing the polycrystalline silicon thin-film forming method according to Embodiment 2.

FIG. 11C is a cross-sectional view showing the polycrystalline silicon thin-film forming method according to Embodiment 2.

FIG. 11D is a cross-sectional view showing the polycrystalline silicon thin-film forming method according to Embodiment 2.

FIG. 12A is a cross-sectional view showing a polycrystalline silicon thin-film forming method according to Embodiment 3.

FIG. 12B is a cross-sectional view showing the polycrystalline silicon thin-film forming method according to Embodiment 3.

FIG. 12C is a cross-sectional view showing the polycrystalline silicon thin-film forming method according to Embodiment 3.

FIG. 12D is a cross-sectional view showing the polycrystalline silicon thin-film forming method according to Embodiment 3.

FIG. 12E is a cross-sectional view showing the polycrystalline silicon thin-film forming method according to Embodiment 3.

FIG. 13 is a cross-sectional view of a solar cell according to Embodiment 4.

FIG. 14 is a cross-sectional view of a solar cell according to a modification of Embodiment 4.

FIG. 15 is a cross-sectional view showing a configuration of a solar cell module according to Embodiment 5.

FIG. 16A shows a solar cell module forming method according to Embodiment 5.

FIG. 16B shows the solar cell module forming method according to Embodiment 5.

FIG. 16C shows the solar cell module forming method according to Embodiment 5.

FIG. 17A shows the solar cell module forming method according to Embodiment 5.

FIG. 17B shows the solar cell module forming method according to Embodiment 5.

FIG. 17C shows the solar cell module forming method according to Embodiment 5.

FIG. 18 is a cross-sectional view showing a configuration of a thin-film transistor according to Embodiment 6.

FIG. 19A shows a thin-film transistor forming method according to Embodiment 6.

FIG. 19B shows the thin-film transistor forming method according to Embodiment 6.

FIG. 19C shows the thin-film transistor forming method according to Embodiment 6.

FIG. 20A shows the thin-film transistor forming method according to Embodiment 6.

FIG. 20B shows the thin-film transistor forming method according to Embodiment 6.

FIG. 20C shows the thin-film transistor forming method according to Embodiment 6.

FIG. 20D shows the thin-film transistor forming method according to Embodiment 6.

FIG. 21 is a cross-sectional view showing the configuration of the thin-film transistor according to Embodiment 6.

FIG. 22 is a top-surface view showing an organic EL display according to Embodiment 7.

FIG. 23 is a cross-sectional view showing the organic EL display according to Embodiment 7.

FIG. 24 is a pixel circuit diagram of a pixel circuit mounted on the organic EL display according to Embodiment 7.

FIG. 25 is a flowchart showing a forming process of the polycrystalline silicon thin film in a conventional technique.

### DESCRIPTION OF EMBODIMENTS

According to an exemplary embodiment disclosed herein, a polycrystalline silicon thin-film forming method includes: preparing a substrate; forming, above the substrate, a precursor of a first silicon thin film including a first polycrystalline silicon phase and a non-crystalline silicon phase; exposing the first polycrystalline silicon phase by etching the precursor of the first silicon thin film by a predetermined chemical etching process in which the non-crystalline silicon phase is etched preferentially over the first polycrystalline silicon phase; and growing, above the first silicon thin film which the first polycrystalline silicon phase is exposed, a second polycrystalline silicon phase using the first polycrystalline silicon phase as a seed crystal by a plasma chemical vapor deposition method, wherein the first polycrystalline silicon phase is formed continuously in a direction perpendicular to a thickness direction of the first silicon thin film.

With this, it is possible to accelerate the crystallization of the second polycrystalline silicon phase which is a major component of the second silicon thin film, using the first polycrystalline silicon phase that is a major component of the first silicon thin film as the seed crystal. As a result, despite being polycrystalline, the second silicon thin film can be formed at a film forming speed of between 60 and 200 nm/min inclusive, which is faster than the conventional film forming speed (equal to or less than 10 nm/min).

Furthermore, the first silicon thin film including the first polycrystalline silicon phase as the major component is formed first above the substrate, and then the second silicon thin film including the second polycrystalline silicon phase as the major component is formed, using the first polycrystalline silicon phase as a seed crystalline layer. Therefore, a second silicon thin film including a good-quality polycrystalline silicon phase as the major component can be formed, without being influenced by so-called base, namely a substrate, an electrode formed on the substrate, or material and crystalline of an interlayer.

Furthermore, in the polycrystalline silicon thin-film forming method according to an exemplary embodiment disclosed herein, the predetermined chemical etching process may be a dry etching process in which the first silicon thin film is irradiated with hydrogen plasma.

Since hydrogen plasma etches the non-crystalline silicon phase faster than etching the polycrystalline silicon phase, the non-crystalline silicon phase can be etched preferentially over the polycrystalline silicon phase. Thus, the predetermined chemical etching process is appropriate in forming of the first silicon thin film including the first polycrystalline silicon phase as the major component.

By irradiating the first silicon thin film with hydrogen plasma, the polycrystalline silicon phase is also irradiated with hydrogen plasma. However, since hydrogen included in hydrogen plasma has the smallest mass from among all of the elements, the crystalline of the polycrystalline silicon phase cannot be destroyed as in a physical sputtering, even when the polycrystalline silicon phase is irradiated with hydrogen plasma. Therefore, in the forming of the second silicon thin film including the second polycrystalline silicon phase as the major component, it is appropriate to use hydrogen plasma to form the first silicon thin film, which includes the first polycrystalline silicon phase having an even crystalline as the major component, as the seed crystal used in the forming of the second silicon thin film including the second polycrystalline silicon phase as the major component.

Furthermore, in the polycrystalline silicon thin-film forming method according to an exemplary embodiment disclosed herein, the forming of the precursor of the first silicon thin film may include: forming a non-crystalline silicon thin film above the substrate; and annealing the non-crystalline silicon thin film to form the precursor of the first silicon thin film including the first polycrystalline silicon phase and the non-crystalline silicon phase.

The non-crystalline silicon thin film has a few selectivity of material and heat resistant temperature of the substrate. Therefore, the non-crystalline silicon thin film can be formed above substrates including various materials, such as a glass substrate, a substrate which a metal film is formed above a glass substrate, or a metal substrate. With this, since the non-crystalline silicon thin film is annealed after the non-crystalline silicon thin film is formed, it is possible to form the precursor of the first silicon thin film, which includes the first polycrystalline silicon phase and the non-crystalline silicon phase, on substrates including various materials, such as a glass substrate, a substrate which a metal film is formed above a glass substrate, or a metal substrate.

Furthermore, in the polycrystalline silicon thin-film forming method according to an exemplary embodiment disclosed herein, the annealing of the non-crystalline silicon thin film may be performed by irradiating the non-crystalline silicon thin film with a laser beam.

With this, when the substrate is a glass substrate, a substrate which a metal film is formed above a glass substrate, or a metal substrate, it is possible to decrease a heat load placed on each of the various materials constituting the substrate. Therefore, the precursor of the first silicon thin film including the first polycrystalline silicon phase and the non-crystalline silicon phase can be formed with minimum thermal deformation and thermal transformation while maintaining a flatness of the substrate.

Furthermore, in the polycrystalline silicon thin-film forming method according to an exemplary embodiment disclosed herein, the first polycrystalline silicon phase included in the first silicon thin film may be granular and may have a crystal grain diameter of approximately 15 nm to approximately 60 nm inclusive.

With this, the grain diameter of the first polycrystalline silicon phase included in the first silicon thin film is made to be approximately 15 nm to approximately 60 nm inclusive, whereby it is possible to make the seed crystal an appropriate seed crystal for growing the second polycrystalline silicon phase at a high speed.

Furthermore, in the polycrystalline silicon thin-film forming method according to an exemplary embodiment disclosed herein, in the growing of the second polycrystalline silicon phase, the second silicon thin film including the second polycrystalline silicon phase as a major component may be formed by growing the second polycrystalline silicon phase using the first polycrystalline silicon phase as the seed crystal.

Furthermore, the polycrystalline silicon thin film forming method according to an exemplary embodiment disclosed herein may further include, after the growing of the second polycrystalline silicon phase, the forming of the first polycrystalline silicon phase, the exposing of the first polycrystalline silicon phase, and the growing of the second polycrystalline silicon phase, again.

Furthermore, a polycrystalline silicon thin-film substrate according to an exemplary embodiment disclosed herein includes: a substrate; and a first silicon thin film formed above the substrate and including a first polycrystalline silicon phase as a major component, and a second silicon thin film formed above the first silicon thin film and including a second polycrystalline silicon phase as a major component, wherein the first silicon thin film is obtained by reforming, as the first silicon thin film, a precursor of the first silicon thin film including the first polycrystalline silicon phase and a non-crystalline silicon phase, by exposing the first polycrystalline silicon phase by etching the precursor of the first silicon thin film by a predetermined chemical etching process in which the non-crystalline silicon phase is etched preferentially over the first polycrystalline silicon phase, the second silicon thin film is formed by growing the second polycrystalline silicon phase, as the second silicon thin film, above the first silicon thin film using the first polycrystalline silicon phase as a seed crystal by the plasma chemical vapor deposition method, and the first silicon thin film has a thin film structure in which the first polycrystalline silicon phase is formed continuously in a direction perpendicular to a thickness direction of the first silicon thin film.

With this, it is possible to obtain a polycrystalline silicon thin-film substrate from a second polycrystalline silicon phase, by growing the first polycrystalline silicon phase included in the first silicon thin film as the seed crystal.

Furthermore, a silicon thin-film solar cell according to an exemplary embodiment disclosed herein includes: the polycrystalline silicon thin-film substrate according to claim 8; a first electrode provided between the substrate of the polycrystalline silicon thin-film substrate and the first silicon thin film; and a second electrode provided above a side of the second silicon thin film, the side being opposite from a side below which the first silicon thin film is formed.

With this, the silicon thin-film solar cell can provide a solar cell including: a first electrode provided between the substrate and the first silicon thin film; and a second electrode provided above a side of the first silicon thin film. The side is opposite from a side below which the first silicon thin film is formed.

Furthermore, a silicon thin-film transistor device according to an exemplary embodiment disclosed herein includes: the polycrystalline silicon thin-film substrate according to claim 8; (i) a source electrode formed over a first end of the first silicon thin film and a first end of the second silicon thin film and (ii) a drain electrode formed over a second end of the first silicon thin film and a second end of the second silicon thin film; a gate insulator film formed (i) in a given region, above the second silicon thin film, where the source electrode and the drain electrode are not formed (ii) and above the source electrode and the drain electrode; and a gate electrode formed (i) above the gate insulator film and (ii) above a region where the first silicon thin film and the second silicon thin film are formed, wherein the first silicon thin film is a first channel layer, and the second silicon thin film is a second channel layer.

With this, the first silicon thin film also serves as an impurity barrier layer which prevents impurity ion, such as Na, from penetrating from the substrate to the second silicon thin film that is the channel layer. Accordingly, a top-gate silicon thin-film transistor device can be provided in which it is not required to form a new impurity barrier layer on the substrate.

Furthermore, a silicon thin-film transistor device according to an exemplary embodiment disclosed herein includes: the polycrystalline silicon thin-film substrate according to claim 8; a gate electrode formed between the substrate and the first silicon thin film; a gate insulator film formed (i) above the gate electrode and (ii) in a region, above the substrate, where the gate electrode is not formed; and (i) a source electrode formed over a first end of the first silicon thin film and a first end of the second silicon thin film and (ii) a drain electrode formed over a second end of the first silicon thin film and a second end of the second silicon thin film; wherein the first silicon thin film is a first channel layer, and the second silicon thin film is a second channel layer.

With this, the first silicon thin film also serves as an impurity barrier layer which prevents impurity ion, such as Na, from penetrating from the substrate to the second silicon thin film that is the channel layer. Accordingly, a bottom-gate silicon thin-film transistor device can be provided in which it is not required to form a new impurity barrier layer on the substrate.

These general and specific aspects may be implemented using a system, a method, an integrated circuit, a computer program, or a computer-readable recording medium such as a CD-ROM, or any combination of systems, methods, integrated circuits, computer programs, or computer-readable recording media.

Hereinafter, certain exemplary embodiments are described in greater detail with reference to the accompanying Drawings.

Each of the exemplary embodiments described below shows a general or specific example. The numerical values, shapes, materials, structural elements, the arrangement and connection of the structural elements, steps, the processing order of the steps etc. shown in the following exemplary embodiments are mere examples, and therefore do not limit the scope of the appended Claims and their equivalents.

Therefore, among the structural elements in the following exemplary embodiments, structural elements not recited in any one of the independent claims are described as arbitrary structural elements.

The following describes embodiments. Although the following description is based on the embodiments below and the drawings attached, the embodiments and the drawings are given for illustrative purpose only and are not intended to limit the scope of the present inventive concept.

### Embodiment 1

The following describes the polycrystalline silicon thin-film forming method according to the present embodiment with taking a polycrystalline silicon thin-film substrate as an example.

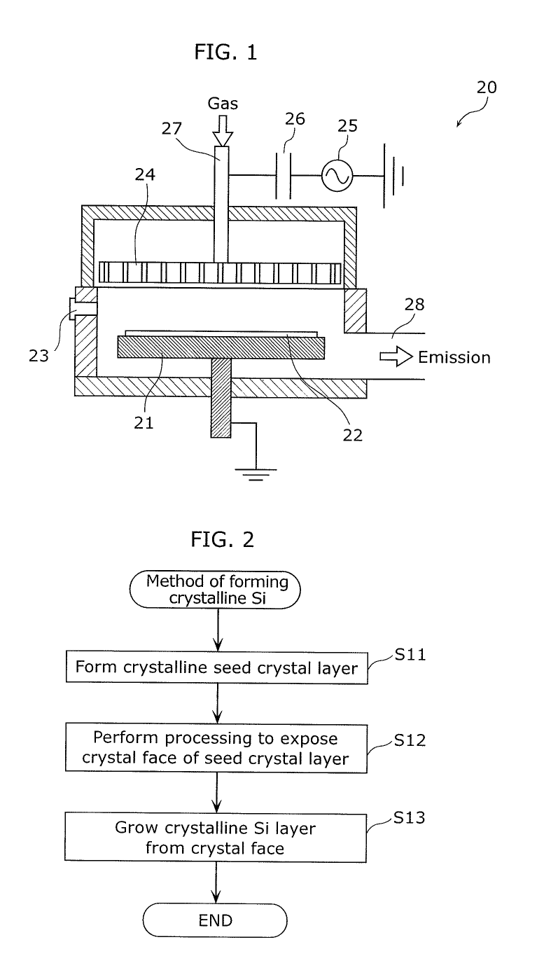

FIG. 1 is a schematic view of a plasma CVD device used in forming of a polycrystalline silicon thin-film substrate in the present embodiment.

As shown in FIG. 1, a plasma CVD device 20 includes a lower electrode 21, a quartz window 23, an upper electrode 24, a high frequency power source 25, a coupling condenser 26, a gas supply line 27, and an exhaust line 28. A substrate above which the polycrystalline silicon thin film is to be formed is placed in a placement portion 22 on the lower electrode 21.

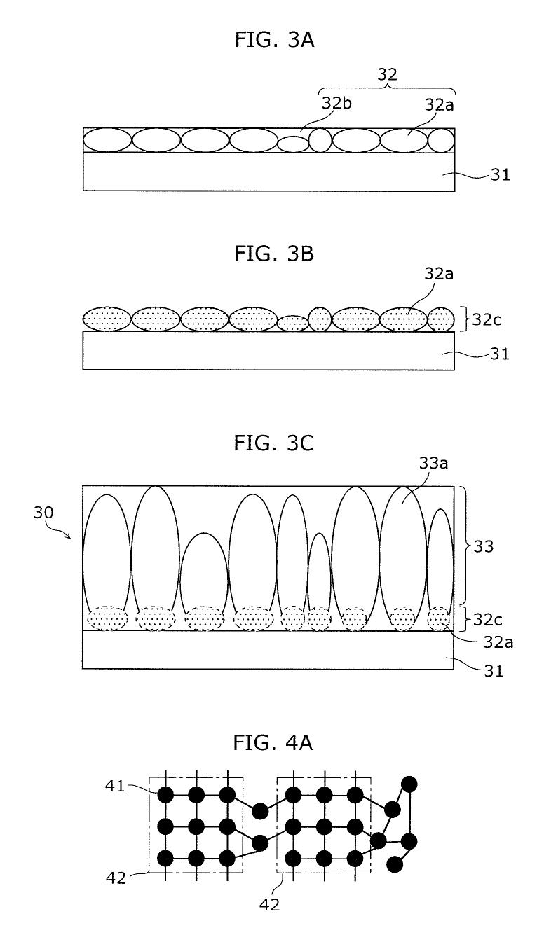

FIG. 2 is a flowchart showing a forming process of the polycrystalline silicon thin film. Furthermore, FIG. 3A through FIG. 3C correspond to the flowchart in FIG. 2 and each shows a forming process of the polycrystalline silicon thin film according to the present embodiment.

A polycrystalline silicon thin-film substrate 30 is formed in the following process.

First, a crystalline seed crystal layer is formed (S11). As shown in FIG. 3A, a glass substrate 31 is prepared, and a precursor 32 of a first silicon thin film is formed above the glass substrate 31, as the seed crystal layer. As shown in FIG. 3A, the precursor 32 of the first silicon thin film includes a first polycrystalline silicon phase 32a and a non-crystalline silicon phase 32b. The precursor 32 includes, for example, polycrystalline silicon (p-Si) or microcrystalline silicon (mc-Si) as the first polycrystalline silicon phase 32a, and amorphous silicon (a-Si) as the non-crystalline silicon phase 32b.

Here, it is possible to also include a preparation process to chemically wash or etch a surface of the glass substrate 31, before forming the precursor 32 of the first silicon thin film. Thus, it is possible to make it difficult for alkali elemental component on the glass surface or impurities on the surface of the glass substrate to penetrate into the precursor 32 of the first silicon thin film from the glass substrate 31.

Next, processing is performed to expose the crystal face of the non-crystalline silicon phase 32b of the precursor 32 of the first silicon thin film (S12). As shown in FIG. 3B, in this processing, the precursor 32 of the first silicon thin film is reformed to a first silicon thin film 32c using the first polycrystalline silicon phase 32a as the major component, by exposing the crystal face of the first polycrystalline silicon phase 32a by removing the non-crystalline silicon phase 32b from the surface of the precursor 32 of the first silicon thin film by a predetermined chemical etching process.

Here, the predetermined chemical etching process performed in S12 is, for example, dry etching in which the precursor 32 of the first silicon thin film is irradiated with hydrogen plasma. Since hydrogen plasma etches the non-crystalline silicon phase 32b faster than etching the first polycrystalline silicon phase 32a, the non-crystalline silicon phase 32b can be etched preferentially over the first polycrystalline silicon phase 32a.

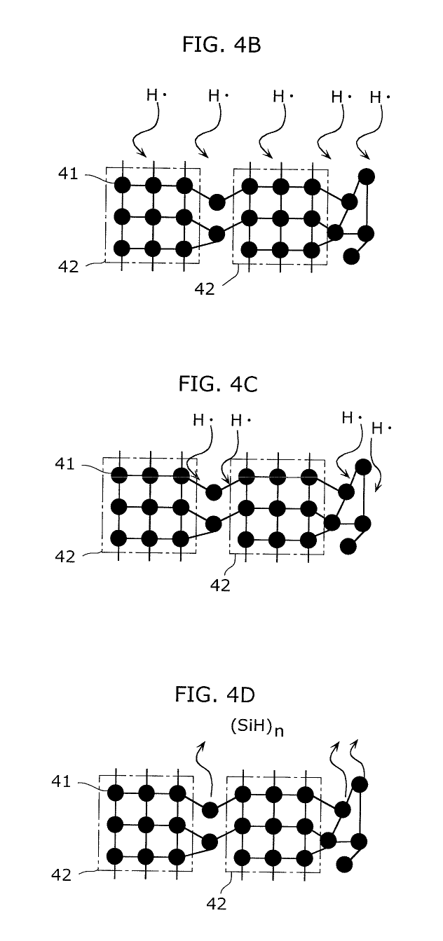

FIG. 4A through FIG. 4D are each a schematic view for illustrating a principle of removing amorphous component, that is the non-crystalline silicon phase 32b, using hydrogen plasma. As shown in FIG. 4A, the precursor 32 of the first silicon thin film is configured with crystal components 42 which are each a bond of a plurality of Si atoms 41. The crystal components 42 are further bonded with one another via other Si atoms 41. Here, when the Si atoms 41 and the crystal components 42 are irradiated with hydrogen radical as shown in FIG. 4B, the bond of the Si atoms 41 bonding the crystal components 42 is broken as showing in FIG. 4C. Thus, as shown in FIG. 4D, the crystal components 42 are separated from one another and removed. Accordingly, the non-crystalline silicon phase 32b is removed and the first polycrystalline silicon phase 32a is exposed. At this time, (SiH)ₙ is generated from the Si atom 41 which the bond is broken and the hydrogen radical. It is to be noted that a hydrogen plasma condition is that, as an example, substrate temperature is 320 degrees Celsius, a pressure is 2 Torr, RF power density is 1.2 W/cm², and an interelectrode distance is 100 mm.

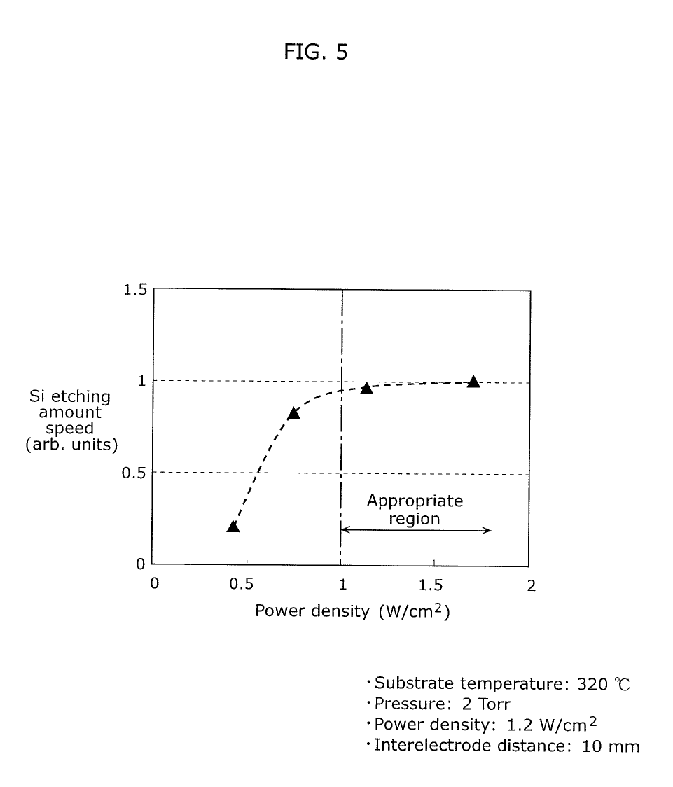

FIG. 5 shows the hydrogen plasma condition used when the above-described dry etching using hydrogen plasma is performed, and shows etching amount speed of the non-crystalline silicon phase 32b with respect to the RF power density. As shown in FIG. 5, the etching amount speed of the non-crystalline silicon phase 32b depends on the RF power density of the dry etching. By adjusting the RF power density in a range between 1 and 1.8 W/cm², in which the etching amount speed is stable, it is possible to perform etching more efficiently.

Then, after the precursor 32 of the first silicon thin film is reformed to the first silicon thin film 32c, the crystalline silicon layer 33 is grown from the crystal face of the first silicon thin film 32c (S13). As shown in FIG. 3C, the crystalline silicon layer 33 including the second polycrystalline silicon phase 33a as the major component is formed, by epitaxially growing the second polycrystalline silicon phase 33a from the crystal face of the first silicon thin film 32c using the first polycrystalline silicon phase 32a of the first silicon thin film 32c as the seed crystal by the plasma CVD method. A CVD film-forming condition is that, as an example, the substrate temperature is 320 degrees Celsius, the pressure is 5 Torr, the RF power density is 0.28 W/cm², the interelectrode distance is 15 mm, SiH₄ throughput is 50 sccm, and H₂ throughput is 300 sccm.

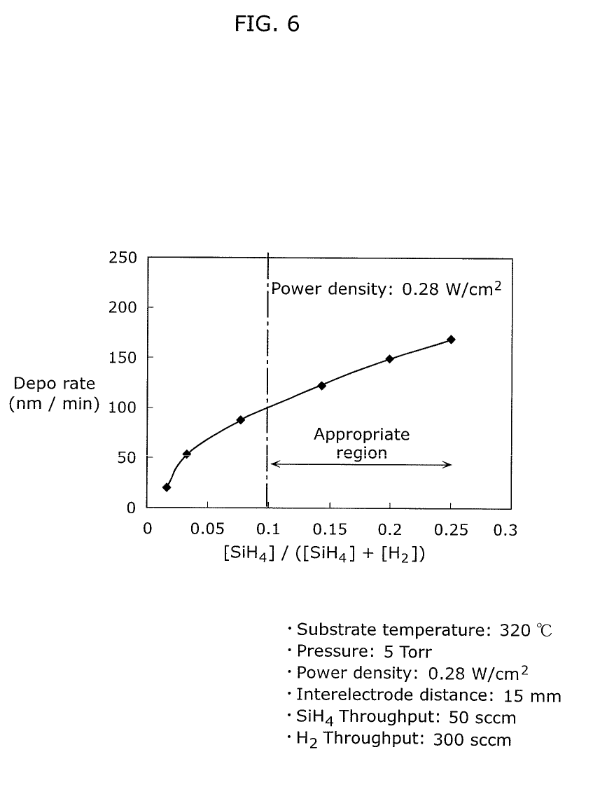

FIG. 6 shows a mc-Si film-forming condition used in growing the crystalline silicon layer 33 from the crystal face of the first silicon thin film 32c, and shows the film-forming speed with respect to the SiH₄ throughput. As shown in FIG. 6, the film-forming speed depends on SiH₄ throughput, specifically, SiH₄ throughput/(SiH₄ throughput+H₂ throughput). By adjusting SiH₄ throughput/(SiH₄ throughput+H₂ throughput) in a range greater than or equal to 0.1, it is possible to form the crystalline silicon layer 33 at a high-speed.

Described next is substrate temperature dependency seen when the non-crystalline silicon phase 32b of the precursor 32 of the first silicon thin film is etched.

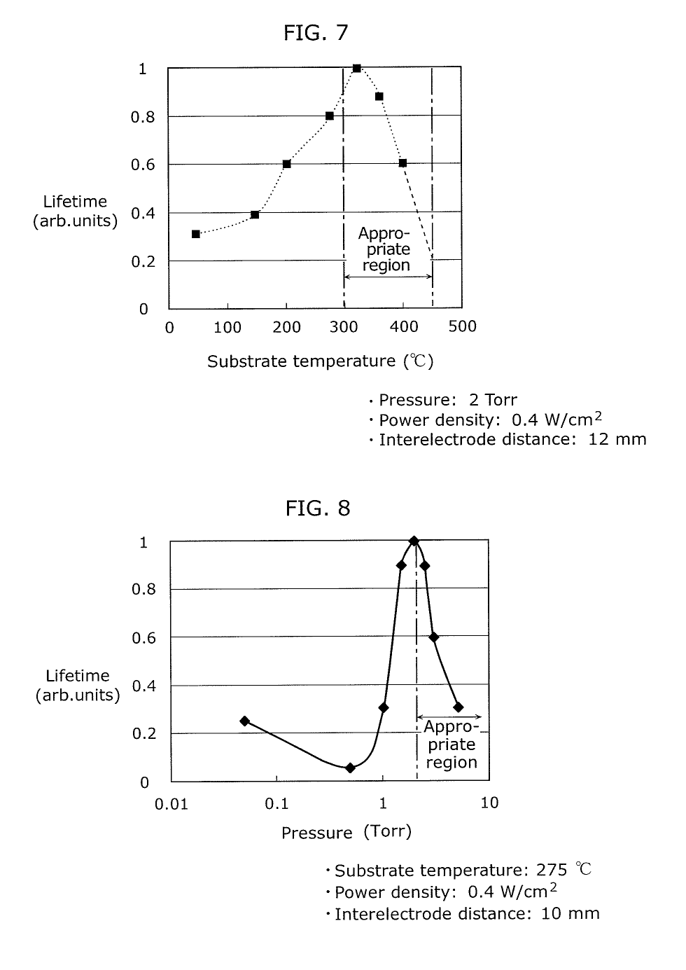

FIG. 7 shows a change in lifetime obtained when the substrate temperature of the polycrystalline silicon thin-film substrate 30 is changed. Lifetime is a time period taken until an exciton (carrier), which is generated when the polycrystalline silicon thin-film substrate 30 is irradiated with light, is trapped in a defect formed in the polycrystalline silicon thin-film substrate 30. In FIG. 7, a high lifetime indicates that much hydrogen radical is generated. That is, a high lifetime indicates that the precursor 32 of the first silicon thin film is irradiated with much hydrogen radical, and the dry etching of the precursor 32 of the first silicon thin film is performed actively.

FIG. 7 shows the substrate temperature dependency of the lifetime under a condition that the pressure is 2 Torr, the RF power density is 0.4 W/cm², and the interelectrode distance is 12 mm. The substrate temperature here indicates not a value obtained by directly measuring the substrate temperature of the polycrystalline silicon thin-film substrate 30, but a set value of the substrate temperature. Accordingly, the actual substrate temperature of the polycrystalline silicon thin-film substrate 30 is lower than the substrate temperature shown in FIG. 7 by 20 to 30 degrees Celsius.

In FIG. 7, in a range from 0 to 300 degrees Celsius of the substrate temperature, since the substrate temperature is insufficient, the precursor 32 of the first silicon thin film formed above the glass substrate 31 is hydrogenated by hydrogen radical generated. Therefore, as shown in FIG. 7, the lifetime is short when the substrate temperature is approximately 100 degrees Celsius, while the lifetime increases as the substrate temperature is higher.

When the substrate temperature reaches approximately 320 degrees Celsius, as shown in FIG. 7, the lifetime starts to decrease. This indicates that when the substrate temperature is set to be higher than or equal to 320 degrees Celsius, the surface of the non-crystalline silicon phase 32b of the precursor 32 of the first silicon thin film is etched with hydrogen radical, whereby defects formed in the surface of the non-crystalline silicon phase 32b increase and lifetime of carriers trapped by these defects decreases. In other words, decrease in the lifetime indicates that more defects are formed which means the surface of the non-crystalline silicon phase 32b is more chipped.

When the substrate temperature reaches greater than or equal to approximately 450 degrees Celsius, hydrogen atoms in the non-crystalline silicon phase 32b fall out, film quality of the precursor 32 of the first silicon thin film is deteriorated, and film quality of the crystalline Si layer 33, which is epitaxially grown using the first polycrystalline silicon phase 32a after etching of the non-crystalline silicon phase 32b, is deteriorated. Therefore, it can be recognized that the substrate temperature greater than or equal to 450 degrees Celsius is not appropriate for etching the non-crystalline silicon phase 32b.

Accordingly, as shown in FIG. 7, it can be recognized that the substrate temperature between approximately 300 degrees Celsius and 450 degrees Celsius inclusive is appropriate for etching the non-crystalline silicon phase 32b.

Although the above-described RF power density of 0.4 W/cm² is out of the optimum range that is between 1 and 1.8 W/cm² shown in FIG. 5, this measurement is conducted under the RF power density out of the optimum range on purpose, in order to recognize the substrate temperature dependency clearly.

Described next is pressure dependency seen when the non-crystalline silicon phase 32b of the precursor 32 of the first silicon thin film is etched.

FIG. 8 shows a change in lifetime obtained when the pressure in the plasma CVD device 20 is changed during etching of the non-crystalline silicon phase 32b of the precursor 32 of the first silicon thin film using hydrogen radical. FIG. 8 shows a result obtained when the pressure dependency is measured under the condition that the substrate temperature is 275 degrees Celsius, the RF power density is 0.4 W/cm², and the interelectrode distance is 10 mm.

As shown in FIG. 8, when the pressure is approximately 0.05 Torr to 0.5 Torr, the lifetime is decreased. It can be recognized that the lifetime is decreased because the amount of generated hydrogen radical is small and the surface of the non-crystalline silicon phase 32b is dry etched by the plasma, and the carriers are trapped by the defects caused by dry etching.

Furthermore, it can be recognized that, when the pressure is approximately 0.5 Torr to 2 Torr, hydrogen radical is increased, whereby the defects formed by dry etching are decreased, and the lifetime is increased, while when the pressure is greater than or equal to 2 Torr, the non-crystalline silicon phase 32b is etched by hydrogen radical, whereby the carriers are trapped by the defects caused by the etching, and the lifetime is decreased. In other words, it can be recognized that, the non-crystalline silicon phase 32b is etched by hydrogen radical when the pressure is greater than or equal to 2 Torr, and therefore the pressure greater than or equal to 2 Torr is appropriate for etching the non-crystalline silicon phase 32b.

Although the above-described RF power density of 0.4 W/cm² is out of the optimum range that is between 1 and 1.8 W/cm² shown in FIG. 5 and the substrate temperature of 275 degrees Celsius is out of the optimum range that is greater than or equal to 450 degrees Celsius shown in FIG. 7, this measurement is conducted under the RF power density and the substrate temperature out of the optimum ranges on purpose, in order to recognize the pressure dependency clearly. In the same manner, in order to recognize the pressure dependency clearly, the interelectrode distance is set to out of the optimum interelectrode distance range that is between 12 mm and 50 mm described later. The interelectrode distance is set to the minimum value 10 mm at which electric discharge is caused in the plasma CVD device 20.

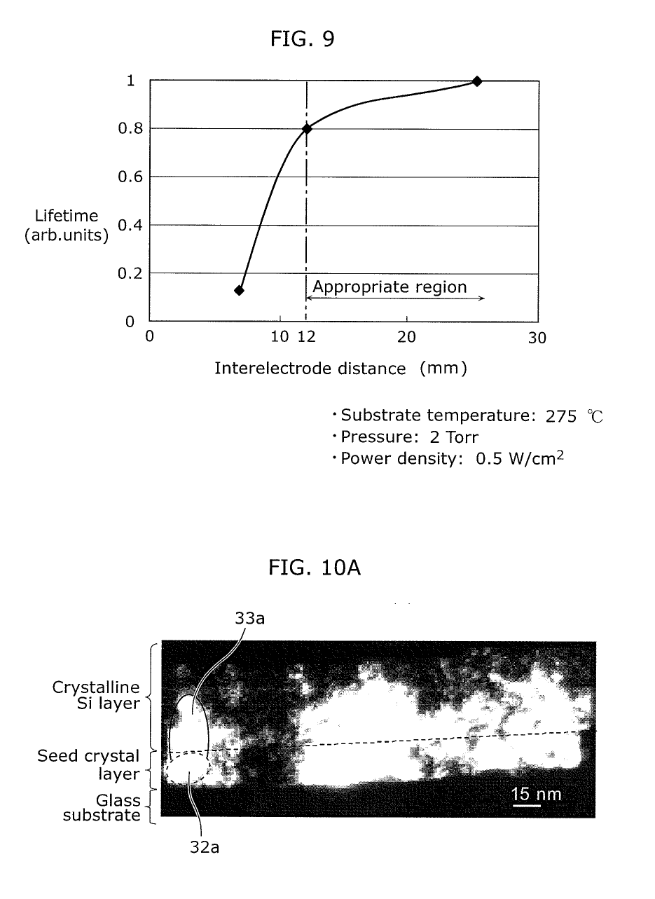

Next, the interelectrode distance dependency is described. FIG. 9 is a graph showing a change in lifetime obtained when the interelectrode distance is changed. FIG. 9 shows a result obtained by measuring the interelectrode distance dependency under the condition that the substrate temperature is 275 degrees Celsius, the pressure is 2 Torr, and the RF power density is 0.5 W/cm².

In FIG. 9, when the interelectrode distance is smaller than or equal to 12 mm, hydrogen radical is not generated sufficiently due to instable electric discharge, and density of hydrogen radical is small. Accordingly, as shown in FIG. 9, the lifetime is decreased when the interelectrode distance is equal to or smaller than 12 mm. Furthermore, when the interelectrode distance is extended, much hydrogen radical is generated, and the lifetime is increased. According to FIG. 9, it can be recognized that the appropriate interelectrode distance for etching the non-crystalline silicon layer 32b of the precursor 32 of the first silicon thin film is equal to or greater than 12 mm. Furthermore, when the interelectrode distance exceeds mm, the lifetime is almost constant. Therefore, given relationships between other conditions, it is recognized that the appropriate interelectrode distance is less than or equal to approximately 50 mm.

It is to be noted that it has been found by the inventors of the present application that hydrogen plasma is hardly generated when the interelectrode distance is equal to or less than 10 mm. Hydrogen plasma is generated even when the interelectrode distance is equal to or less than 10 mm, however, the electric discharge is unstable. If conditions on the pressure, power, and firing step, for example, are changed, stable plasma can be generated even when the interelectrode distance is approximately 10 mm. Accordingly, it is possible to etch the non-crystalline silicon phase 32b even when the interelectrode distance is approximately 10 mm.

Although the above-described RF power density of 0.5 W/cm² is out of the optimum range that is between 1 and 1.8 W/cm² shown in FIG. 5 and the substrate temperature of 275 degrees Celsius is out of the optimum range that is greater than or equal to 450 degrees Celsius shown in FIG. 7, this measurement is conducted under the RF power density and the substrate temperature out of the optimum ranges on purpose, in order to recognize the pressure dependency clearly. Accordingly, the optimum range of the interelectrode distance will be broader when the RF power density is in the optimum range that is between 1 and 1.8 W/cm² as shown in FIG. 5.

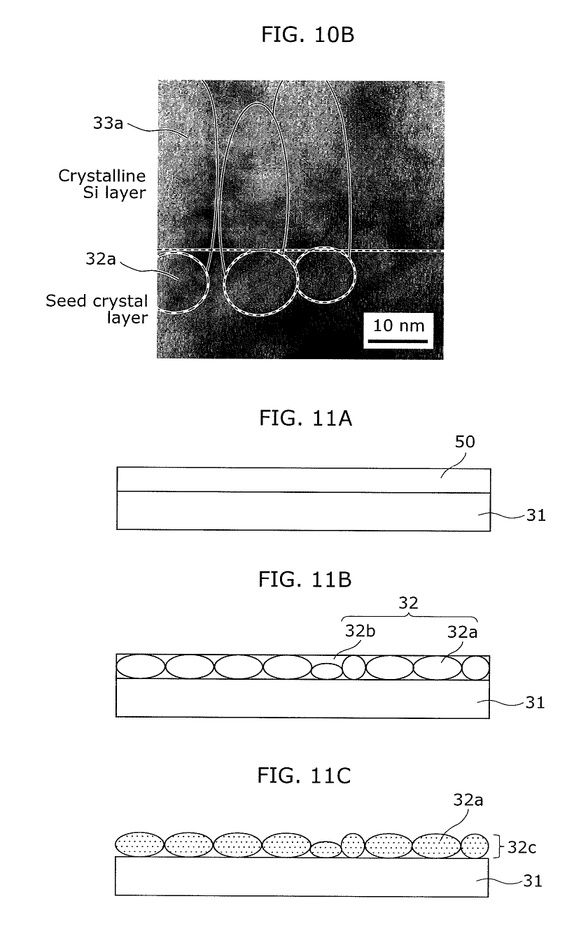

FIG. 10A and FIG. 10B are each an example of the cross-section TEM picture of the polycrystalline silicon thin-film substrate 30 formed by the above-described forming method and condition. FIG. 10A is an observatory picture with a dark field (high magnification), while FIG. 10B is an observatory picture with a light field (high magnification). In FIG. 10A and FIG. 10B, the light portion is a portion in which the crystallization is proceeding. Furthermore, the oval portion indicated by the broken line is the first polycrystalline silicon phase 32a that is the seed crystal, and the oval portion indicated by the solid line is the second polycrystalline silicon phase 33a.

According to FIG. 10A and FIG. 10B, the second polycrystalline silicon phase 33a is epitaxially grown using the first polycrystalline silicon phase 32a as the seed crystal, and the crystalline silicon layer 33 is formed continuously from the first silicon thin film 32c that is the seed crystal layer formed above the glass substrate 31. Furthermore, after the first silicon thin film 32c, which includes the first polycrystalline silicon phase 32a indicated by the broken line as the major component, is reformed from the precursor of the first silicon thin film, the crystalline silicon layer 33, which includes the second polycrystalline silicon phase 33a indicated by the solid line as the second polycrystalline silicon phase 33a, is formed. Therefore, the crystalline silicon layer 33 can be formed which includes good-quality polycrystalline silicon phase as the major component, without being influenced by so-called base, namely the glass substrate 31, the electrode formed on the glass substrate 31, or the material and crystalline of the interlayer.

It can be recognized that the thickness of the first silicon thin film 32c and the crystalline silicon layer 33 is approximately 60 nm at this time. This means the polycrystalline silicon thin-film substrate 30 of a thick film, which is desired, is obtained by the above-described forming method. The film forming speed at this time is 100 nm/min.

Accordingly, with the present embodiment, the polycrystalline silicon thin film of a thick film can be obtained at a high speed by the above-described polycrystalline silicon thin-film forming method.

### Embodiment 2

The following describes Embodiment 2 according to the present disclosure. The polycrystalline silicon thin-film forming method according to the present embodiment is different from the polycrystalline silicon thin-film forming method according to Embodiment 1 in that (i) a non-crystalline silicon thin film is preliminarily formed above a glass substrate and (ii) a precursor of a first silicon thin film including a first polycrystalline silicon phase and a non-crystalline silicon phase is formed by annealing the non-crystalline silicon thin film.

The non-crystalline silicon thin film is annealed by, for example, heating the glass substrate above which the non-crystalline silicon thin film is formed until the glass substrate reaches at a predetermined temperature. The temperature for annealing is, for example, between 500 degrees Celsius and 800 degrees Celsius inclusive and annealing is continued for 30 seconds to 3 hours.

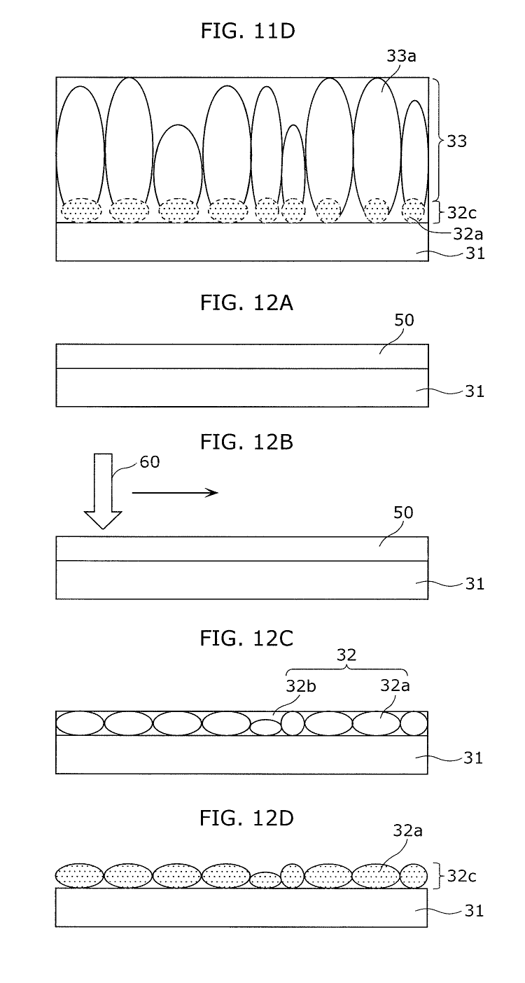

FIG. 11A to FIG. 11D are each a cross-sectional view showing the polycrystalline silicon thin-film forming method according to the present embodiment.

A polycrystalline silicon thin-film substrate according to the present embodiment is formed in the following process.

First, as shown in FIG. 11A, a non-crystalline silicon thin film 50 is formed above a glass substrate 31. Then, by heating the glass substrate until the glass substrate reaches at a temperature in a range between 500 degrees Celsius and 800 degrees Celsius inclusive, as shown in FIG. 11B, the precursor 32 of the first silicon thin film including the first polycrystalline silicon phase 32a and the non-crystalline silicon phase 32b is formed.

Then, in the same manner as in Embodiment 1, as shown in FIG. 11C, the first silicon thin film 32c including the first polycrystalline silicon phase 32a as the major component is formed by exposing the crystal face of the first polycrystalline silicon phase 32a by removing the non-crystalline silicon phase 32b from the surface of the precursor 32 of the first silicon thin film by the predetermined chemical etching process.

Furthermore, as shown in FIG. 11D, the crystalline silicon layer that is the second silicon thin film including the second polycrystalline silicon phase 33a as the major component is formed by epitaxially growing the second polycrystalline silicon phase 33a from the crystal face of the first silicon thin film 32c by the plasma CVD method.

Accordingly, with the present embodiment, the polycrystalline silicon thin film of a thick film can be obtained at a high speed by the above-described polycrystalline silicon thin-film forming method.

### Embodiment 3

The following describes Embodiment 3 according to the present disclosure. The polycrystalline silicon thin-film forming method according to the present embodiment is different from the polycrystalline silicon thin-film forming method according to Embodiment 1 in that (i) a non-crystalline silicon thin film is preliminarily formed above a glass substrate and (ii) a precursor of a first silicon thin film including a first polycrystalline silicon phase and a non-crystalline silicon phase is formed by annealing the non-crystalline silicon thin film by laser irradiation.

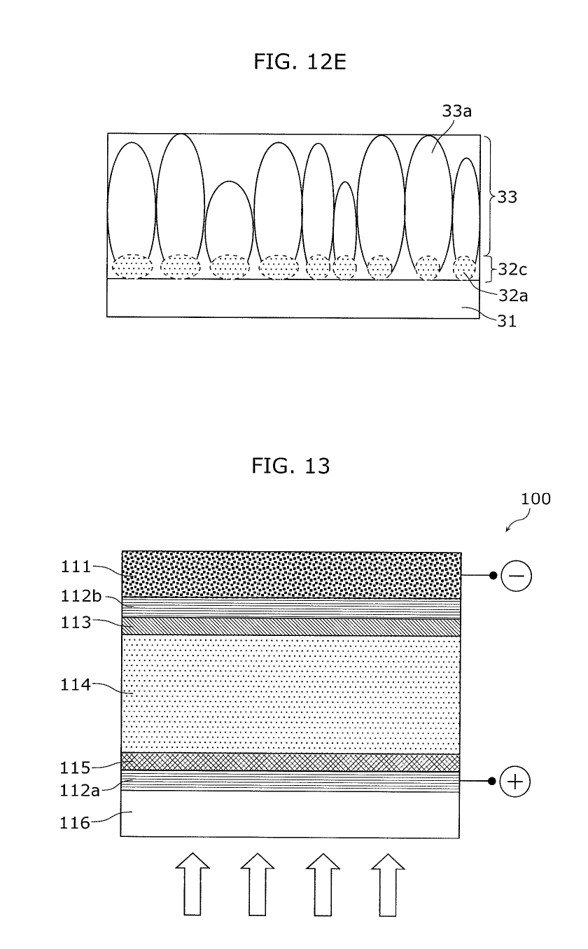

The non-crystalline silicon thin film is annealed by irradiating the non-crystalline silicon thin film with a laser beam. The laser used here is, as an example, a CW laser having a wavelength of 532 nm, energy of 70 kW/cm², and a scanning speed of the laser of 350 mm/s. FIG. 12A through FIG. 12E are each a cross-sectional view showing the polycrystalline silicon thin-film forming method according to the present embodiment.

A polycrystalline silicon thin film according to the present embodiment is formed in the following process.

First, as shown in FIG. 12A, a non-crystalline silicon thin film 50 is formed above a glass substrate 31. Then, as shown in FIG. 12B, the non-crystalline silicon thin film 50 is irradiated with a laser beam 60 under the above-described condition. As shown in FIG. 12C, a precursor 32 of a first silicon thin film including a first polycrystalline silicon phase 32a and a non-crystalline silicon phase 32b is formed.

Then, in the same manner as in Embodiment 1, as shown in FIG. 12D, a first silicon thin film 32c including the first polycrystalline silicon phase 32a as the major component is formed by exposing the crystal face of the first polycrystalline silicon phase 32a by removing the non-crystalline silicon phase 32b from the surface of the precursor 32 of the first silicon thin film by the predetermined chemical etching process.

Furthermore, as shown in FIG. 12E, a crystalline silicon layer 33 including a second polycrystalline silicon phase 33a as the major component is formed by epitaxially growing the second polycrystalline silicon phase 33a from the crystal face of the first silicon thin film 32c by the plasma CVD method.

By annealing the non-crystalline silicon thin film by laser irradiation in the above manner, it is possible to decrease a heat load placed on each of the various materials included in the substrate. Therefore, the precursor of the first silicon thin film including the first polycrystalline silicon phase and the non-crystalline silicon phase can be formed with minimum thermal deformation and thermal transformation and while maintaining a flatness of the substrate.

### Embodiment 4

The following describes Embodiment 4 according to the present disclosure. In the present embodiment, description is provided on a solar cell including a polycrystalline silicon thin-film substrate.

FIG. 13 is a cross-sectional view of a solar cell 100 according to the present embodiment. As shown in FIG. 13, the solar cell 100 includes: a glass substrate 116; a transparent electrode 112a; a p-crystalline Si layer 115, an i-crystalline Si layer 114, and an n-crystalline Si layer 113, which form a photoelectric conversion unit; a transparent electrode 112b; and a metal electrode 111. The transparent electrode 112a and the transparent electrode 112b are formed with ITO, and the metal electrode is formed with Ag. Furthermore, the p-crystalline Si layer 115, the i-crystalline Si layer 114, and the n-crystalline Si layer 113 are each formed into 20 to 100 nm, 2 to 3 μm, and 20 to 100 nm in this order.

When solar light is incident from below the glass substrate 116, that is from the direction indicated by the arrow shown in FIG. 13, the received light is immediately converted into electricity using a photovoltaic effect by the photoelectric conversion unit configured with the n-crystalline Si layer 113, the i-crystalline Si layer 114, and the p-crystalline Si layer 115, and the electricity is outputted as a voltage between the metal electrode 111 and the transparent electrode 112a.

Here, the glass substrate 116 corresponds to the substrate in the present disclosure. The p-crystalline Si layer 115 is a seed crystal layer and corresponds to the first silicon thin film in the present disclosure. The i-crystalline Si layer 114 is a layer epitaxially grown from the p-crystalline Si layer 115, and corresponds to the second silicon thin film in the present disclosure. The transparent electrode 112a corresponds to the first electrode, the metal electrode 111 and the transparent electrodes 112b correspond to the second electrodes, in the present disclosure.

Forming the solar cell 110 with the polycrystalline silicon thin-film substrate makes it possible to form a solar cell requiring forming of a polycrystalline silicon thin film of a thick film at a high speed.

### Modification of Embodiment 4

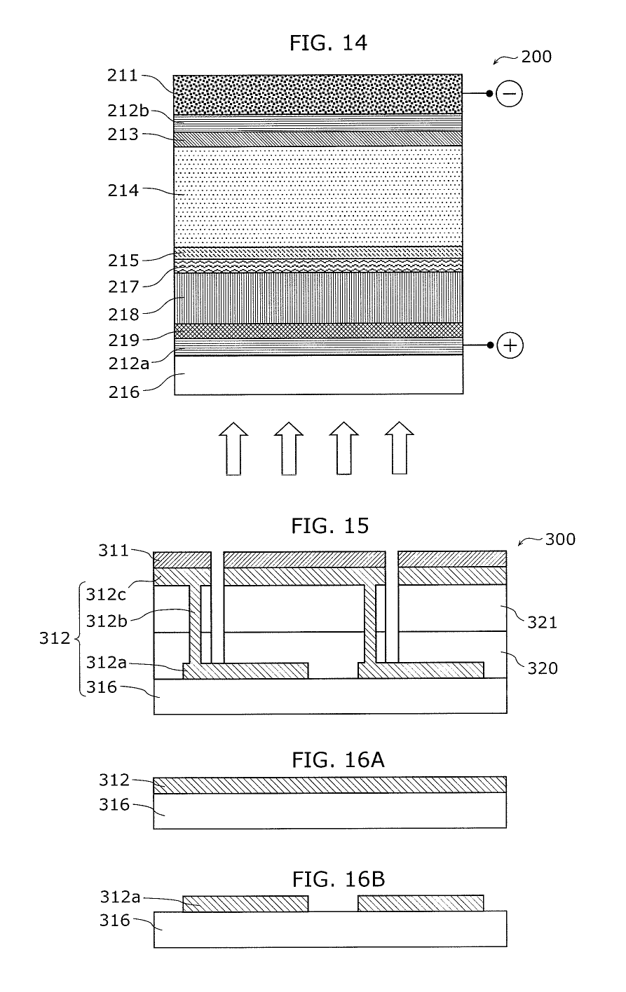

The following describes an example of a modification of Embodiment 4. FIG. 14 is a cross-sectional view of a solar cell according to the present modification. Although the solar cell 100 according to above-described Embodiment 4 includes the photoelectric conversion unit of a single layer configured with the n-crystalline Si layer 113, the i-crystalline Si layer 114, and the p-crystalline Si layer 115, the solar cell may be configured with a tandem configuration including two layers of the photoelectric conversion unit as shown in FIG. 14.

A solar cell 200 shown in FIG. 14 includes a glass substrate 216, a transparent electrode 212a that is the first electrode, a p-crystalline Si layer 219, an i-non-crystalline Si layer 218, an n-non-crystalline Si layer 217, a p-crystalline Si layer 215, an i-crystalline Si layer 214, an n-crystalline Si layer 213, and a transparent electrode 212b and a metal electrode 221 that are each the second electrode.

Here, the n-non-crystalline Si layer 217 and the i-non-crystalline Si layer 218 are formed with amorphous silicon (a-Si), and the n-non-crystalline Si layer 217, the i-non-crystalline Si layer 218, and the p-crystalline Si layer 219 constitute a first photoelectric conversion unit. The thickness of the i-non-crystalline Si layer 218 is, for example, approximately 500 nm.

The n-crystalline Si layer 213, the i-crystalline Si layer 214, and the p-crystalline Si layer 215 are formed with microcrystalline silicon (mc-Si) having a crystal grain diameter of approximately 15 nm to approximately 60 nm inclusive, and the n-crystalline Si layer 213, the i-crystalline Si layer 214, and the p-crystalline Si layer 215 constitute a second photoelectric conversion unit. The thickness of the i-crystalline Si layer 214 is, for example, approximately 2 to 3 μnm.

The transparent electrodes 212a and 212b are formed with ITO and the metal electrode is formed with Ag, for example.

When solar light is incident from below the glass substrate 216, that is from the direction indicated by the arrow shown in FIG. 14, the received light is immediately converted into electricity using a photovoltaic effect by (i) the first photoelectric conversion unit configured with the n-non-crystalline Si layer 217, the i-non-crystalline Si layer 218, and the p-crystalline Si layer 219 and (ii) the second photoelectric conversion unit configured with the n-crystalline Si layer 213, the i-crystalline Si layer 214, and the p-crystalline Si layer 215, and the electricity is outputted as a voltage between the metal electrode 211 and the transparent electrode 212a.

At this time, with the tandem configuration of the solar cell including the first photoelectric conversion unit and the second photoelectric conversion unit, the solar light having a plurality of spectra can be simultaneously converted into electricity.

Furthermore, by forming the first polycrystalline silicon phase with microcrystalline silicon, it is possible to make the first polycrystalline silicon phase an appropriate seed crystal for growing the second polycrystalline silicon phase at a high speed. Thus, the second silicon thin film can be grown at an even higher speed.

### Embodiment 5

The following describes Embodiment 5 according to the present disclosure. In the present embodiment, description is provided on a solar cell module including a polycrystalline silicon thin-film substrate.

FIG. 15 is a cross-sectional view showing a configuration of a solar cell module 300 according to the present embodiment. As shown in FIG. 15, the solar battery module 300 includes a glass substrate 316, a first photoelectric conversion unit 320 configured with an a-Si p-i-n layer, a second photoelectric conversion unit 321 configured with a mc-Si p-i-n layer, a transparent electrode 312, and a metal electrode 311. The solar battery module 300 is a solar cell having a tandem configuration of the first photoelectric conversion unit 320 and the second photoelectric conversion unit 321.

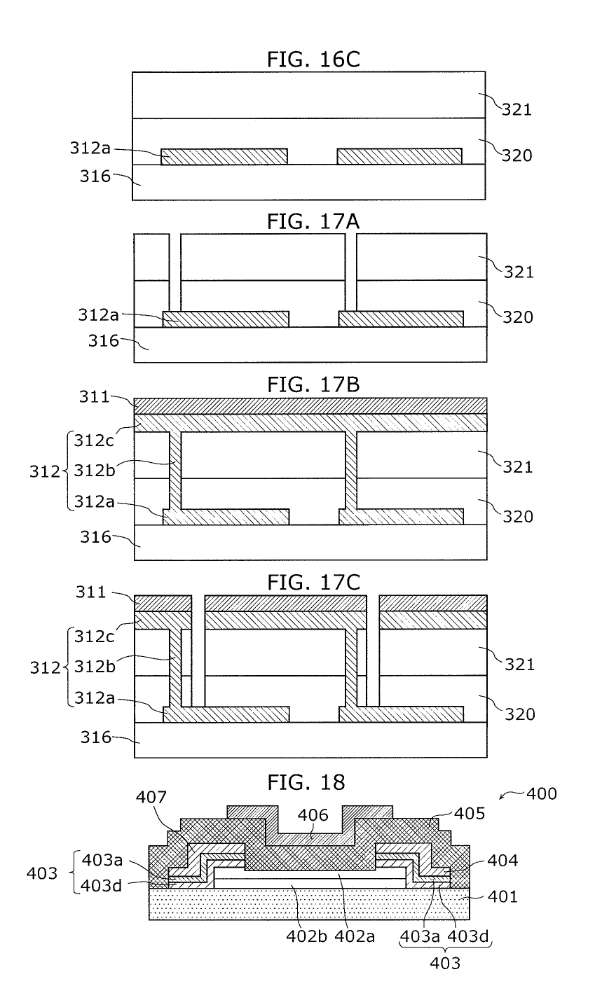

FIG. 16A through FIG. 16C and FIG. 17A through FIG. 17C each shows a forming method of the solar battery module 300 shown in FIG. 15.

The following describes the forming method of the solar battery module 300.

First, as shown in FIG. 16A, the glass substrate 316 is prepared and the transparent electrode 312a is formed above the glass substrate 316 by sputtering, for example.

Then, as shown in FIG. 16B, laser scribe is performed on the transparent electrode 312a and a groove is formed at a predetermined position. Thus, the transparent electrode 312a in a predetermined form is formed.

Next, as shown in FIG. 16C, the first photoelectric conversion unit 320 configured with the a-Si p-i-n layer is formed above the glass substrate 316 above which the transparent electrode 312a is formed. The configuration of the first photoelectric conversion unit 320 is similar to that of the first photoelectric conversion unit shown in the modification of Embodiment 4, namely the n-non-crystalline Si layer 217, the i-non-crystalline Si layer 218, and the p-crystalline Si layer 219.

Furthermore, the second photoelectric conversion unit 321 configured with the mc-Si p-i-n layer is formed above the photoelectric conversion unit 320. The configuration of the second conversion unit 321 is similar to that of the second photoelectric conversion unit shown in the modification of Embodiment 4, namely the n-crystalline Si layer 213, the i-crystalline Si layer 214, and the p-crystalline Si layer 215.

Next, as shown in FIG. 17A, laser scribe is performed on the first photoelectric conversion unit 320 and the second photoelectric conversion unit 321, and contact holes each having part of the transparent electrode 312a as the bottom surface are formed at predetermined positions.

Next, as shown in FIG. 17B, a transparent electrode 312b is formed inside each of the contact holes, and the transparent electrode 312c is formed above a top surface of the photoelectric conversion unit 321. The metal electrode 311 is further formed above the transparent electrode 312c.

Then, as shown in FIG. 17C, the first photoelectric conversion unit 320, the second photoelectric conversion unit 321, the transparent electrode 312c, and the metal electrode 311 are separated into predetermined regions by laser scribe, and a plurality of solar cells are formed.

In this manner, with the configuration including the polycrystalline silicon thin-film substrate, a solar battery module including a plurality of solar cells can be formed at a high speed.

### Embodiment 6

The following describes Embodiment 6 according to the present disclosure. In the present embodiment, description is provided on a top-gate transistor including the polycrystalline silicon thin-film substrate shown in Embodiment 1.

FIG. 18 is a cross-sectional view showing a configuration of a top-gate transistor 400 in the present embodiment. As shown in FIG. 18, the transistor 400 includes a substrate 401, a crystalline Si layer 402a, a seed crystalline Si layer 402b, a contact layer 403 including a high-concentration layer 403a and an i-Si layer 403d, a drain electrode 404, a gate insulator film 405, a gate electrode 406, and a source electrode 407. Here, the seed crystalline Si layer 402b corresponds to the first silicon thin film in the present disclosure, and the crystalline Si layer 402a corresponds to the second silicon thin film in the present disclosure.

Furthermore, the seed crystalline Si layer 402b as the first silicon thin film also serves as an impurity barrier layer which prevents impurity ion, such as Na, from penetrating from the substrate to the crystalline Si layer 402a which serves as the second silicon thin film that is the channel layer. The seed crystalline Si layer 402b is the first channel layer and the crystalline Si layer 402a is the second channel layer, in the present disclosure.

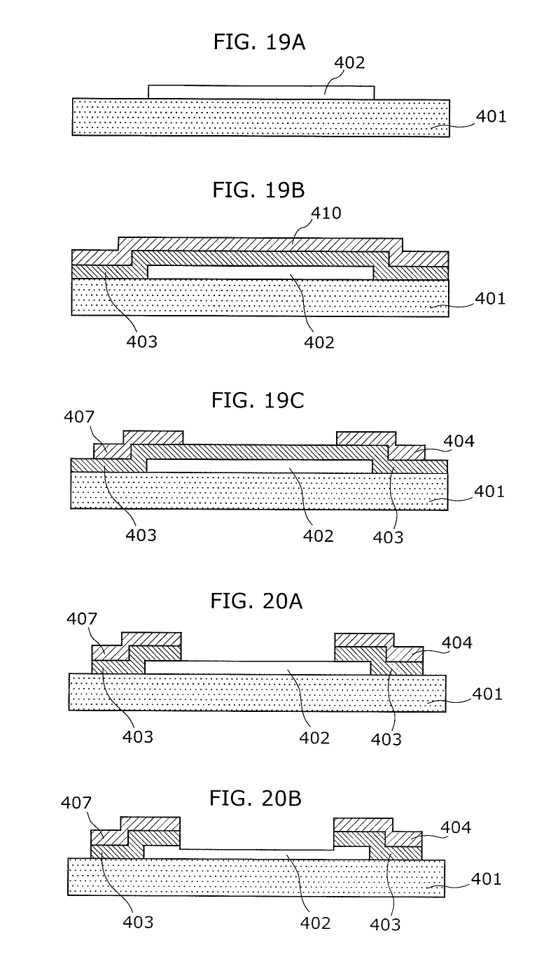

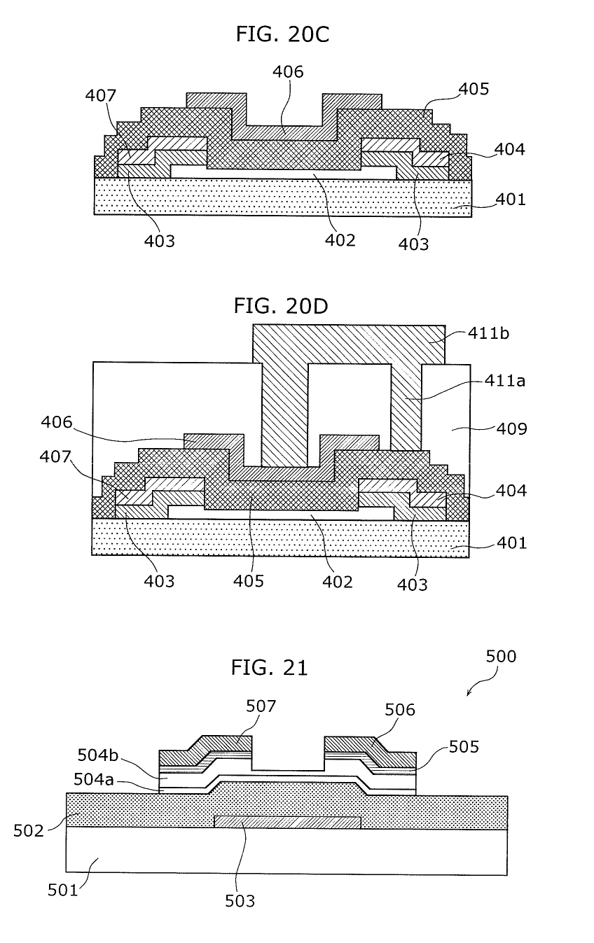

FIG. 19A through FIG. 19C and FIG. 20A through FIG. 20C each shows a method of forming the transistor 400 shown in FIG. 18.

The following describes the method of forming the transistor 400.

First, as shown in FIG. 19A, a substrate 401 is prepared and a polycrystalline silicon thin film 402 is formed above the substrate 401. The polycrystalline silicon thin film 402 is the same as the polycrystalline silicon thin film shown in Embodiment 1, and has a configuration in which the crystalline Si layer 402a that is the second polycrystalline silicon phase is grown from the seed crystalline Si layer 402b that is the first polycrystalline silicon phase. Furthermore, the polycrystalline silicon thin film 402 may be patterned in an island at a predetermined position.

Next, as shown in FIG. 19B, the contact layer 403 including the high-concentration layer 403a and the i-Si layer 403d is formed. The contact layer 403 is formed by depositing high-concentration amorphous silicon by the plasma CVD method. A metal layer 410 is formed above the contact layer 403 by sputtering.

Next, as shown in FIG. 19C, the drain electrode 404 and the source electrode 407 are formed by patterning the metal layer 410.

Furthermore, as shown in FIG. 20A and FIG. 20B, the polycrystalline silicon thin film 402 is exposed by dry etching the contact layer 403. Here, when dry etching is performed with adopting an endpoint detection mechanism, which detects the polycrystalline silicon thin film 402, only the contact layer 403 is dry etched and the polycrystalline silicon thin film 402 is exposed as shown in FIG. 20A. When the dry etching is performed without adopting the endpoint detection mechanism, the contact layer 403 and part of the polycrystalline silicon thin film 402 are dry etched as shown in FIG. 20B.

Next, as shown in FIG. 20C, the gate insulator film 405 is formed from above the substrate 401 which is exposed with the polycrystalline silicon thin film 402 by the plasma CVD method. The gate insulator film 405 is formed above the polycrystalline silicon thin film 402, the drain electrode 404, the source electrode 407, and the substrate 401. Then, the gate electrode 406 is formed above the gate insulator film 405 by metal sputtering and patterning.

Furthermore, as shown in FIG. 20D, an interlayer insulator film 409 is deposited from above the substrate 401 above which the gate electrode 406 is formed. Then, contact holes are formed by laser scribe for example, an electrode 411a is formed inside each of the contact holes, and an electrode 411b is formed above a top surface of the interlayer insulating film 409.

In this manner, with the configuration including the polycrystalline silicon thin-film substrate, the top-gate thin-film transistor 400 can be formed at a high speed. Furthermore, since the seed crystalline Si layer 402b also serves as an impurity barrier layer which prevents impurity ion, such as Na, from penetrating from the substrate to the crystalline Si layer 402a that is the channel layer, there is no need to form a new impurity barrier layer on the substrate.

This can decrease the time required for forming the thin-film transistor.

### Modification of Embodiment 6

The following describes a modification of Embodiment 6 according to the present disclosure. Description on the top-gate transistor 400 has been provided in Embodiment 5. In the present modification, a bottom-date transistor 500 is described.

FIG. 21 is a cross-sectional view showing a configuration of the bottom-date transistor 500 according to the present modification. As shown in FIG. 21, the transistor 500 includes a substrate 501, a gate insulator film 502, a gate electrode 503, a seed crystalline Si layer 504a that is the first polycrystalline silicon phase, a crystalline Si layer 504b that is the second polycrystalline silicon phase, a contact layer 505, a drain electrode 506, and a source electrode 507. The transistor 500 has a configuration in which the gate of the transistor is formed above the gate electrode 503 formed above the substrate 501. The seed crystalline Si layer 504a is the first channel layer and the crystalline Si layer 504b is the second channel layer, in the present disclosure.

Description on a method of forming the transistor 500 is omitted since it is similar to that of the transistor shown in Embodiment 5.

In this manner, with the configuration including the polycrystalline silicon thin-film substrate, the bottom-gate thin-film transistor 500 can be formed at a high speed.

### Embodiment 7

The following describes Embodiment 7 according to the present disclosure. In the present embodiment, an organic EL display is described in which a pixel circuit is configured with the above-described polycrystalline silicon thin-film substrate transistor.

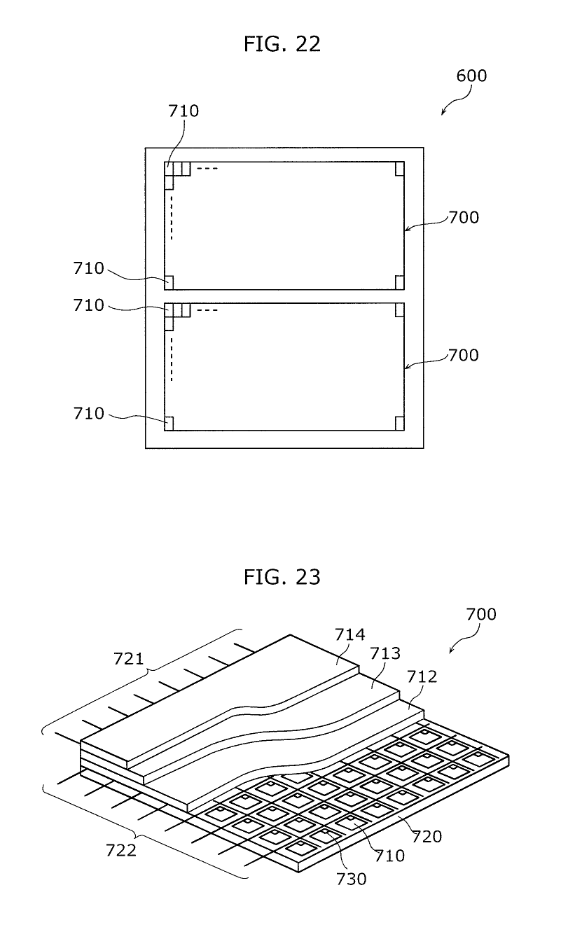

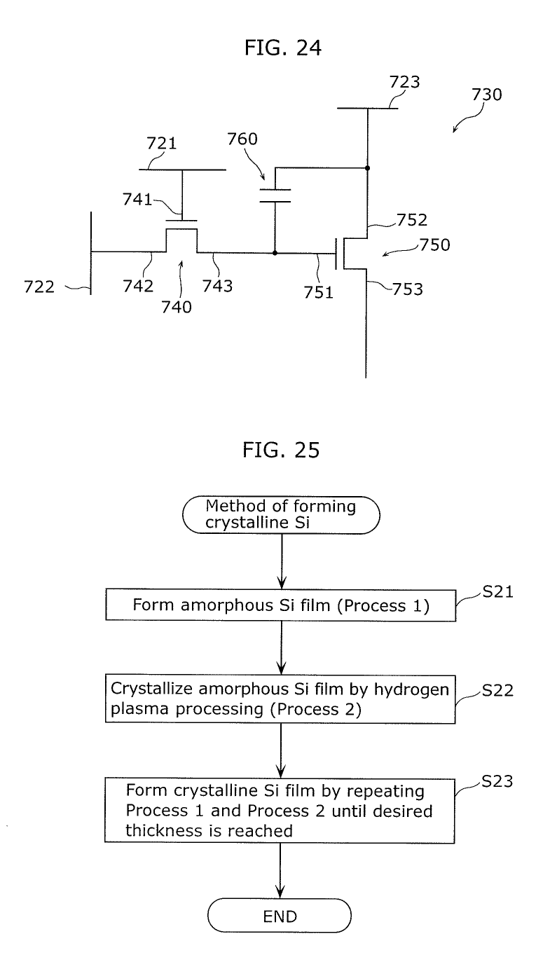

FIG. 22 is top-surface view showing a configuration of the organic EL display according to the present embodiment, FIG. 23 is a cross-sectional view showing the configuration of the organic EL display, and FIG. 24 is a pixel circuit diagram of a pixel circuit mounted on the organic EL display.

As shown in FIG. 22, an organic EL display 600 includes a TFT array substrate 700 including a plurality of pixels 710.

As shown in FIG. 23, the TFT array substrate 700 includes a thin-film semiconductor device for display 720 in which the pixels 710 are arranged in a matrix, an anode 712 arranged above the thin film semiconductor device for display 720, an organic EL layer 713, and a transparent cathode 714. Furthermore, each of the pixels 710 includes a pixel circuit 730, and a gate line 721 and a source line 722 connected to the pixel circuit 730 are provided.

As shown in FIG. 24, the pixel circuit 730 includes a first transistor 740, a second transistor 750, a condenser 760, and a power line 723.

The first transistor 740 includes a gate electrode 741, a source electrode 742, and a drain electrode 743. The second transistor 750 includes a gate electrode 751, a drain electrode 752, and a source electrode 753. The gate line 721 is connected to the gate electrode 741 of the first transistor 740, and the source line 722 is connected to the source electrode 742 of the first transistor 740.

The first transistor 740 and the second transistor 750 are, for example, configured with the bottom-gate thin-film transistor configured with the above-described polycrystalline silicon thin-film substrate. With the above configuration, it is possible to form the pixel circuit 730 of the pixel 710 included in the display 600 at a high speed.

The herein disclosed subject matter is to be considered descriptive and illustrative only, and the appended Claims are of a scope intended to cover and encompass not only the particular embodiments disclosed, but also equivalent structures, methods, and/or uses.

For example, although dry etching using hydrogen plasma is applied as the predetermined chemical etching process to etch the non-crystalline silicon phase of the precursor of the first silicon thin film in the above-described embodiments, the chemical etching process is not limited to the above and other methods may be applied. For example, dry etching using Ar plasma may be applied.

Although the second polycrystalline silicon phase is formed by the plasma CVD method in the above-described embodiments, other methods may be applied so long as the second polycrystalline silicon phase is grown using the first polycrystalline silicon phase as the seed crystal. Furthermore, the condition for forming the second polycrystalline silicon phase is not limited to the conditions indicated in the above-described embodiments, and may be changed as appropriate.

Although the annealing of the non-crystalline silicon thin film is performed by the CW laser irradiation in the above-described embodiments, other types of laser may be used. Furthermore, the condition for annealing is not limited to the conditions indicated in the above-described embodiments, and may be changed as appropriate.

Furthermore, other embodiments achieved by combining arbitrary constituents in the above embodiments, modification examples obtained by applying various modifications conceived by those skilled in the art to the above embodiments within a scope that does not deviate from the spirit of the present disclosure, and various devices including the polycrystalline silicon thin-film substrate, the silicon thin film solar battery, and the silicon thin-film transistor device according to the present disclosure are also included in the present disclosure. For example, a liquid crystal display or an organic EL display is also included in the present disclosure as a display including the silicon thin-film transistor according to the present disclosure.

### INDUSTRIAL APPLICABILITY

The polycrystalline silicon thin-film forming method and the polycrystalline silicon thin film according to one or more exemplary embodiments disclosed herein are applicable to polycrystalline silicon thin-film substrates, polycrystalline silicon thin-film solar cells, and silicon thin-film transistor devices, and particularly useful for panel displays such as an organic EL panel displays.

1. A polycrystalline silicon thin-film forming method, the method comprising:
preparing a substrate;
forming, above the substrate, a precursor of a first silicon thin film including a first polycrystalline silicon phase and a non-crystalline silicon phase;
exposing the first polycrystalline silicon phase by etching the precursor of the first silicon thin film by a predetermined chemical etching process in which the non-crystalline silicon phase is etched preferentially over the first polycrystalline silicon phase; and
growing, above the first silicon thin film which the first polycrystalline silicon phase is exposed, a second polycrystalline silicon phase using the first polycrystalline silicon phase as a seed crystal by a plasma chemical vapor deposition method,
wherein the first polycrystalline silicon phase is formed continuously in a direction perpendicular to a thickness direction of the first silicon thin film.

2. The polycrystalline silicon thin-film forming method according to claim 1,
wherein the predetermined chemical etching process is a dry etching process in which the first silicon thin film is irradiated with hydrogen plasma.

3. The polycrystalline silicon thin-film forming method according to claim 1,
wherein the forming of the precursor of the first silicon thin film includes:
forming a non-crystalline silicon thin film above the substrate; and
annealing the non-crystalline silicon thin film to form the precursor of the first silicon thin film including the first polycrystalline silicon phase and the non-crystalline silicon phase.

4. The polycrystalline silicon thin-film forming method according to claim 3,
wherein the annealing of the non-crystalline silicon thin film is performed by irradiating the non-crystalline silicon thin film with a laser beam.

5. The polycrystalline silicon thin-film forming method according to claim 1,
wherein the first polycrystalline silicon phase included in the first silicon thin film is granular and has a crystal grain diameter of approximately 15 nm to approximately 60 nm.

6. The polycrystalline silicon thin-film forming method according claim 1,
wherein, in the growing of the second polycrystalline silicon phase,
the second silicon thin film including the second polycrystalline silicon phase as a major component is formed by growing the second polycrystalline silicon phase using the first polycrystalline silicon phase as the seed crystal.

7. The polycrystalline silicon thin-film forming method according claim 1, further comprising,
after the growing of the second polycrystalline silicon phase, the forming of the first polycrystalline silicon phase, the exposing of the first polycrystalline silicon phase, and the growing of the second polycrystalline silicon phase, again.

8. A polycrystalline silicon thin-film substrate comprising:
a substrate; and
a first silicon thin film formed above the substrate and including a first polycrystalline silicon phase as a major component, and a second silicon thin film formed above the first silicon thin film and including a second polycrystalline silicon phase as a major component,
wherein the first silicon thin film is obtained by reforming, as the first silicon thin film, a precursor of the first silicon thin film including the first polycrystalline silicon phase and a non-crystalline silicon phase, by exposing the first polycrystalline silicon phase by etching the precursor of the first silicon thin film by a predetermined chemical etching process in which the non-crystalline silicon phase is etched preferentially over the first polycrystalline silicon phase,
the second silicon thin film is formed by growing the second polycrystalline silicon phase, as the second silicon thin film, above the first silicon thin film using the first polycrystalline silicon phase as a seed crystal by the plasma chemical vapor deposition method, and
the first silicon thin film has a thin film structure in which the first polycrystalline silicon phase is formed continuously in a direction perpendicular to a thickness direction of the first silicon thin film.

9. A silicon thin-film solar cell comprising:
the polycrystalline silicon thin-film substrate according to claim 8;
a first electrode provided between the substrate of the polycrystalline silicon thin-film substrate and the first silicon thin film; and
a second electrode provided above a side of the second silicon thin film, the side being opposite from a side below which the first silicon thin film is formed.

10. A silicon thin film transistor device comprising:
the polycrystalline silicon thin-film substrate according to claim 8;
(i) a source electrode formed over a first end of the first silicon thin film and a first end of the second silicon thin film and (ii) a drain electrode formed over a second end of the first silicon thin film and a second end of the second silicon thin film;
a gate insulator film formed (i) in a given region, above the second silicon thin film, where the source electrode and the drain electrode are not formed (ii) and above the source electrode and the drain electrode; and
a gate electrode formed (i) above the gate insulator film and (ii) above a region where the first silicon thin film and the second silicon thin film are formed,
wherein the first silicon thin film is a first channel layer, and the second silicon thin film is a second channel layer.

11. A silicon thin-film transistor device comprising:
the polycrystalline silicon thin-film substrate according to claim 8;
a gate electrode formed between the substrate and the first silicon thin film;
a gate insulator film formed (i) above the gate electrode and (ii) in a region, above the substrate, where the gate electrode is not formed; and
(i) a source electrode formed over a first end of the first silicon thin film and a first end of the second silicon thin film and (ii) a drain electrode formed over a second end of the first silicon thin film and a second end of the second silicon thin film;
wherein the first silicon thin film is a first channel layer, and the second silicon thin film is a second channel layer.
